(19) United States
(12) Patent Application Publication
(10) Pub. No.: US 2024/0297317 A1
(43) Pub. Date: Sep. 5, 2024

(54) METHOD AND APPARATUS OF DETECTING PROTON EXCHANGE MEMBRANE FUEL CELL OPERATING STATE

(71) Applicant: University Of Science And Technology Of China, Hefei (CN)

(72) Inventors: Lei MAO, Hefei (CN); Yuning SUN, Hefei (CN); Chen ZHANG, Hefei (CN); Zhongyong LIU, Hefei (CN); Qiang WU, Hefei (CN)

(21) Appl. No.: 18/548,021

(22) PCT Filed: Mar. 1, 2021
(86) PCT No.: PCT/CN2021/078463

§ 371 Date: Aug. 25, 2023

(51) Int. Cl. H01M 8/04664; G01R 33/04; H01M 8/04298

(52) U.S. Cl. CPC H01M 8/04671; H01M 8/04305; G01R 33/04

(57) ABSTRACT

Provided are a method and an apparatus of detecting PEMFC (proton exchange membrane fuel cell) operating state. The method includes: arranging a fluxgate sensor on PEMFC cathode surface and at a position opposite to a measurement point on the cathode surface; when PEMFC is operating, continuously measuring a magnetic field variation of a magnetic field of the measurement point changing with time by using the fluxgate sensor; and determining PEMFC operating state according to a corresponding relationship between the magnetic field variation and PEMFC operating state.

### TECHNICAL FIELD

The present disclosure relates to the field of proton exchange membrane fuel cell (PEMFC) state identification technology, and in particular, to a method and an apparatus of detecting PEMFC operating state.

### BACKGROUND

With the consumption of fossil fuels and the environmental deterioration caused by use of fossil fuels for a long time, researches on clean energy has attracting more and more attention. PEMFC has advantages of zero pollution, high energy utilization rate, low working temperature, low noise and the like, so that PEMFC has been applied to fields of automobiles, aviation, distributed power stations, portable equipment and the like.

Generally, PEMFC mainly consists of a bipolar plate 4, a membrane electrode assembly (MEA), a sealing member and the like, and PEMFC durability and reliability are major barriers limiting wide applications of PEMFC. The general reliability maintenance measures are to adopt a fault diagnosis technology to evaluate PEMFC operating state, and further adopt control maintenance measures to guarantee PEMFC operating reliability and durability.

In the related methods, performing fault diagnosis on PEMFC by using electromagnetic field data are mainly classified into two types: one is to utilize an embedded micro current acquisition card to evaluate PEMFC state through an acquired current density distribution in MEA of PEMFC; and the other is to arrange fluxgates around a circumference of MEA of PEMFC (as shown in FIG. 4a), and evaluate PEMFC state through acquired magnetic field distribution data or by using magnetic field data to backward derive a current density.

### SUMMARY

In view of the above, a main objective of the present disclosure is to provide a method and apparatus of detecting PEMFC operating state, so as to at least partially solve at least one of the above-mentioned technical problems.

In order to achieve the above-mentioned objective, the technical solution of the present disclosure is as follows.

As an aspect of the present disclosure, a method of detecting PEMFC operating state is provided, including: arranging a fluxgate sensor on PEMFC cathode surface and at a position opposite to a measurement point on the cathode surface; when PEMFC is operating, continuously measuring a magnetic field variation of a magnetic field of the measurement point changing with time by using the fluxgate sensor; and determining PEMFC operating state according to a corresponding relationship between the magnetic field variation and PEMFC operating state.

As another aspect of the present disclosure, an apparatus of detecting PEMFC operating state is provided, including: a fluxgate sensor arranged on PEMFC cathode surface and at a position opposite to a measurement point on the cathode surface, wherein when PEMFC is operating, the fluxgate sensor is capable of continuously measuring a magnetic field variation of a magnetic field of the measurement point changing with time, so as to determine PEMFC operating state according to the magnetic field variation.

As another aspect of the present disclosure, a simulation method of detecting PEMFC operating state is provided, including: arranging a fluxgate sensor on PEMFC cathode surface and at a position opposite to a measurement point on the cathode surface; performing simulations on different PEMFC operating states, respectively; and for the simulation of each operating state, continuously measuring a magnetic field variation of a magnetic field of the measurement point changing with time by using the fluxgate sensor, so as to determine a corresponding relationship between the magnetic field variation and PEMFC operating state.

### BRIEF DESCRIPTION OF THE DRAWINGS

FIG. 1a is a schematic work diagram of a PEMFC.

FIG. 1b is a schematic diagram of a main current and an excited magnetic field of the main current inside a PEMFC.

FIG. 1c is a schematic diagram of a membrane current and an excited magnetic field of the membrane current inside a PEMFC.

FIG. 2a is a distribution diagram of a main current of a PEMFC simulation model and a magnetic field of the main current.

FIG. 2b is a distribution diagram of a membrane current of a PEMFC simulation model and a of a magnetic field of the membrane current.

FIG. 3a is a distribution diagram of a membrane current of a PEMFC simulation model in a normal state.

FIG. 3b is a distribution diagram of a magnetic field generated by a membrane current of a PEMFC simulation model in a normal state.

FIG. 3c is a distribution diagram of a membrane current of a PEMFC simulation model in a fault state.

FIG. 3d is a distribution diagram of a magnetic field generated by a membrane current of a PEMFC simulation model in a fault state.

FIG. 4a is a schematic diagram of an existing apparatus of detecting PEMFC operating state.

FIG. 4b is a schematic structural diagram of an apparatus of detecting PEMFC operating state according to the present disclosure.

FIG. 5 is a flowchart of a method of detecting PEMFC operating state according to the present disclosure.

FIG. 6 is a flowchart of a simulation method of detecting PEMFC operating state according to the present disclosure.

FIG. 7 is a schematic diagram of a position of a measurement point of a cathode magnetic field in an embodiment of the present disclosure.

FIG. 8a is a magnetic field variation corresponding to the measurement point shown in FIG. 7 in a water flooding fault state in an embodiment of the present disclosure.

FIG. 8b is a magnetic field variation corresponding to the measurement point shown in FIG. 7 in a dehydration fault state in an embodiment of the present disclosure.

### REFERENCE NUMERALS

1. proton exchange membrane (PEM), 2. cathode, 3. anode, 4. bipolar plate, 10. Fluxgate sensor, 20. bracket, 21. base, 22. sliding seat, 23. lifting rod, 30. PEMFC, 31. air inlet, 32. air outlet, 33. hydrogen inlet, 34. three measurement points.

### DETAILED DESCRIPTION OF EMBODIMENTS

In order to make objectives, technical solutions and advantages of the present disclosure more apparent and understandable, the present disclosure is further described in detail below in combination with specific embodiments and with reference to the accompanying drawings.

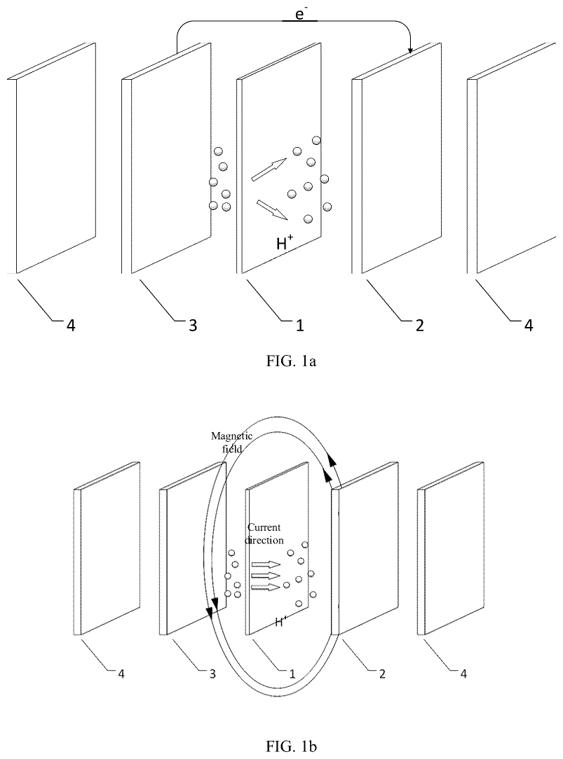

FIG. 1a is a schematic work diagram of a PEMFC. As shown in FIG. 1a, PEMFC mainly consists of a bipolar plate 4, MEA, a sealing member and the like. MEA mainly consists of PEM 1, an anode 3, and a cathode 2. When PEMFC is in operation, hydrogen and oxygen (air) are injected into an anode and a cathode, respectively. With catalyst, hydrogen molecules of the anode are decomposed into hydrogen ions and electrons. The hydrogen ions reach the cathode through PEM and react with oxygen molecules to generate water. The electrons form a complete loop through an external circuit.

In a process of performing PEMFC fault diagnosis through electromagnetic field data, the following problems exist: when an embedded micro current is used to acquire an current density distribution in MEA so as to evaluate PEMFC state, hardware is required to be embedded into PEMFC, which may affect PEMFC state and working condition to a certain extent, thereby affecting an analysis result; when fluxgates are arranged around a circumference of MEA to collect magnetic field data around MEA so as to evaluate PEMFC state, it is necessary to derive a surface magnetic field distribution of MEA through a mathematical model, which not only increases a complexity of a state recognition process, but also brings an additional error, resulting in an inaccurate recognition result.

In a process of realizing the present disclosure, it is found that magnetic field on PEM cathode surface may be directly used to detect PEMFC operating state, which not only solves an impact of the embedded hardware on PEMFC state, but also provides the magnetic field distribution data that may characterize an entire MEA surface, so as to conduct real-time monitoring and analysis on PEMFC operating state variation.

In the following, the inventive concept of the present disclosure and a rationality of a detection method proposed based on the inventive concept will be explained first through a generation mechanism of PEMFC induction magnetic field.

As shown in FIG. 1a, when PEMFC is operating, hydrogen ions generated by oxidizing hydrogen at the anode 3 pass through PEM 1 and reach the cathode 2 to react with oxygen to generate water. The moving hydrogen ions generate a current, and the current has two moving directions: one is perpendicular to PEM 1 (a main current) and the other is parallel to PEM 1 (a membrane current), as shown in FIG. 1b and FIG. 1c below. However, since the current in PEMFC is only concentrated within MEA region, a magnetic field (the magnetic field shown in FIG. 1b) excited by the main current may only be measured through the fluxgate installed close to MEA, while a magnetic field (the magnetic field shown in FIG. 1c) generated by the membrane current may be measured outside PEMFC bipolar plate.

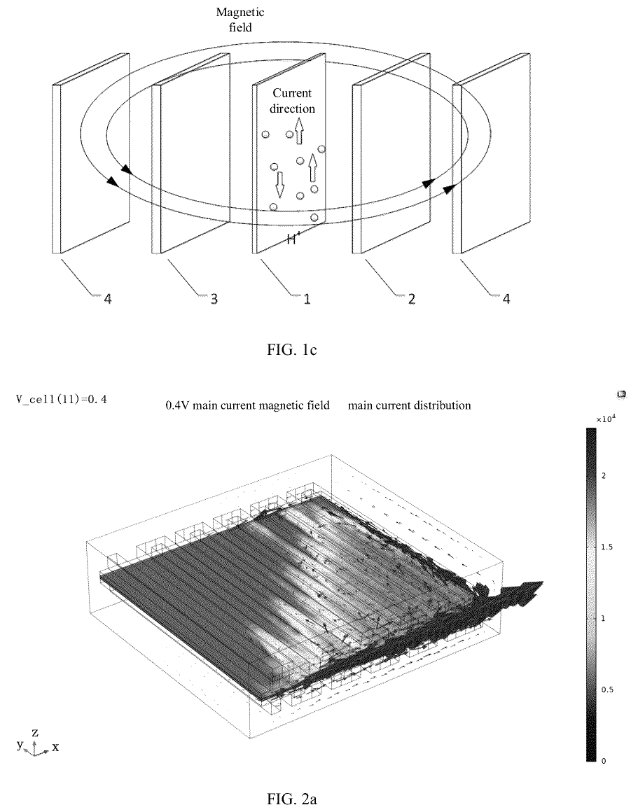

According to Biot-Savart Law, a magnetic induction intensity generated by a current element is proportional to a size of the current element. In FIG. 2a and FIG. 2b, distribution results of currents in different directions in MEA and magnetic fields when PEMFC voltage is 0.4 V are analyzed through a PEMFC simulation model. A lower right side of the simulation model is an air inlet, and an upper left side of the simulation model is an air outlet. A direction and a length of the arrow represent a direction and a magnitude of the magnetic field, respectively. As shown in FIG. 2, for both the main current and the membrane current, there is a corresponding relationship between a current density distribution and an amplitude and a distribution of a corresponding magnetic field. Therefore, the amplitude and the distribution of the membrane current may be evaluated by detecting the magnetic field outside PEMFC bipolar plate.

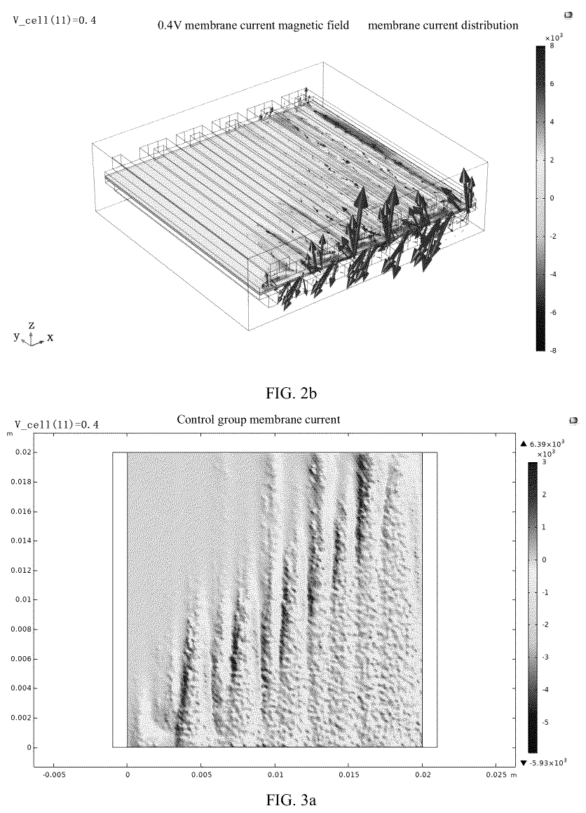

Moreover, based on the aforementioned PEMFC simulation model, by further analyzing variations of amplitudes and distributions of the membrane current and its generated magnetic field caused by variations in PEMFC state, it can be seen that detecting PEMFC operating state by measuring the external magnetic field of PEMFC bipolar plate in the present disclosure is reasonable. FIG. 3a and FIG. 3b show distributions of the membrane current and its PEMFC magnetic field in a normal state, and FIG. 3c and FIG. 3d show distributions of the membrane current and its PEMFC magnetic field in a fault state. In the drawings, a rectangular part is an indicated fault region. It can be seen that in PEMFC fault state, the amplitudes and the distributions of the membrane current and the corresponding magnetic field vary significantly. Therefore, real-time and accurate recognition of PEMFC operating state may be achieved through detection and analysis on the external magnetic field of PEMFC bipolar plate.

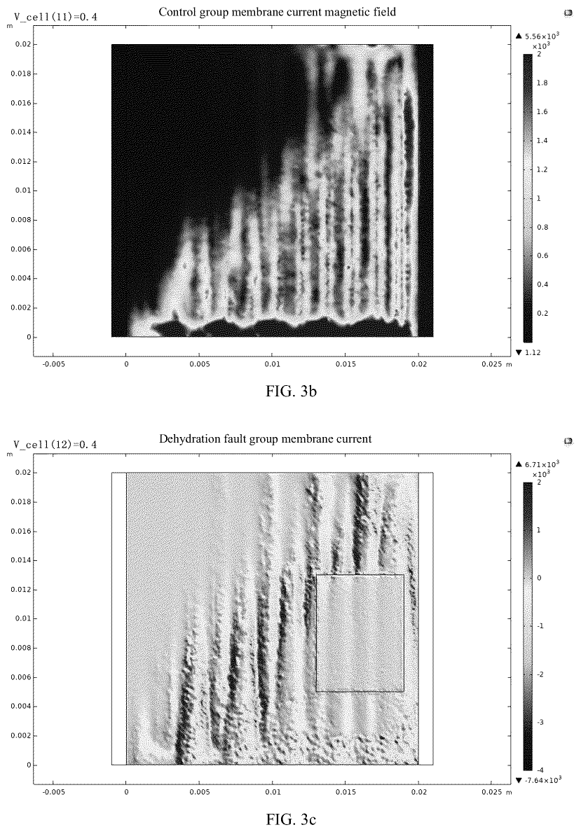

Based on the above content, the present disclosure provides a method and an apparatus of detecting PEMFC operating state. FIG. 4b is a schematic structural diagram of an apparatus of detecting PEMFC operating state according to the present disclosure. As shown in FIG. 4b, the detection apparatus of the present disclosure includes a fluxgate sensor 10 arranged on PEMFC cathode surface and at a position opposite to a measurement point 34 on the cathode surface.

In some embodiments of the present disclosure, the fluxgate sensor 10 may adopt a conventional structure in the art, as long as the fluxgate sensor 10 may measure a magnetic field intensity at the position of the measurement point. For example, a parallel gate fluxgate sensor, an orthogonal gate fluxgate sensor, or a hybrid fluxgate sensor may be used. Optionally, the fluxgate sensor 10 is a rod type fluxgate in the parallel gate fluxgate sensor.

As shown in FIG. 4b, the fluxgate sensor 10 may be arranged at positions opposite to three measurement points 34, respectively, ant the three measurement points are respectively located at an air inlet 31, an air outlet 32, and a middle position between the air inlet 31 and the air outlet 32 on PEMFC 30 cathode surface. However, positions and the number of the measurement points are not limited to this, and the measurement points may be located at more other positions, such as at a hydrogen inlet 33 and the like, so as to better monitor variations of the magnetic field at different positions on the cathode surface.

In some embodiments of the present disclosure, the fluxgate sensor 10 is configured to be movable in three dimensions in a space to facilitate adjustment of a position of the fluxgate relative to the cathode surface, including a position in a direction parallel to the cathode surface and a distance from the cathode surface, so as to select suitable measurement points for magnetic field measurement.

As shown in FIG. 4b, the detection apparatus further includes a bracket 20 for installing the fluxgate sensor 10 so as to adjust the fluxgate sensor 10 to move in a three-axis direction. More specifically, the bracket 20 includes a base 21, a sliding seat 22, and a lifting rod 23, where the sliding seat 22 is arranged on the base 21 and may move in first and second directions relative to the base 21, the lifting rod 23 is arranged on the sliding seat 22 and may move in a third direction relative to the sliding seat 22, and the lifting rod 23 is provided with the fluxgate sensor 10. The first direction, the second direction, and the third direction are perpendicular to each other.

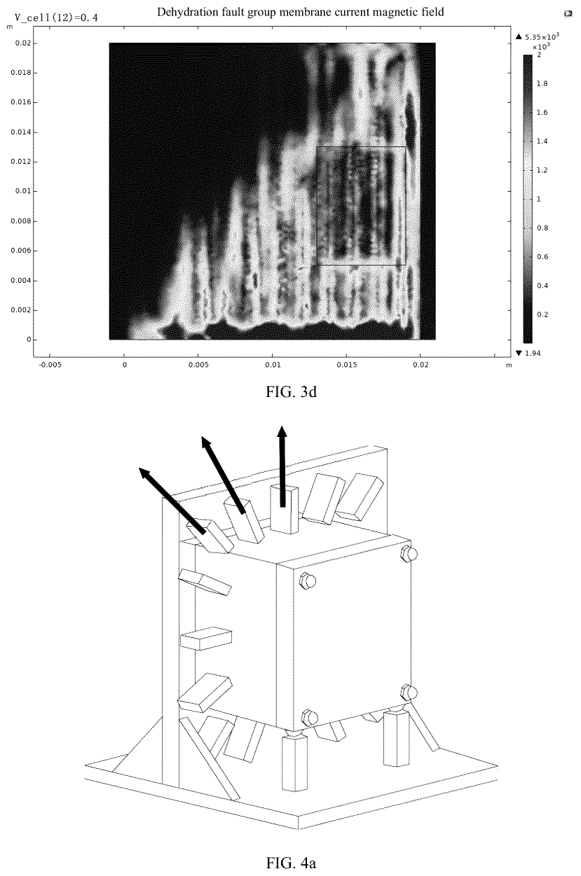

Based on the above-mentioned detection apparatus, the present disclosure provides a method of detecting PEMFC operating state. FIG. 5 is a flowchart of a method of detecting PEMFC operating state according to the present disclosure. As shown in FIG. 4b and FIG. 5, the detection method of the present disclosure includes step A to step C.

In step A, the fluxgate sensor 10 is arranged on PEMFC 30 cathode surface and at the position opposite to the measurement point 34 on the cathode surface. That is, by arranging the detection apparatus and selecting the appropriate magnetic field measurement point, the fluxgate sensor may be used to measure the magnetic field data at different positions on PEMFC cathode surface.

In step B, when PEMFC 30 is operating, the fluxgate sensor 10 is used to continuously measure a magnetic field variation of a magnetic field of the measurement point 34 changing with time.

It should be noted that at this point, a magnetic field result measured by the fluxgate sensor 10 at the measurement point is under an influence of a steady-state magnetic field and a detection device. In order to accurately measure the magnetic field generated by the membrane current, the detection method of the present disclosure further includes step B′: when PEMFC 30 is not in operation, the fluxgate sensor 10 is used to measure a steady-state magnetic field intensity of the measurement point.

At this point, step B specifically includes sub step B1 to sub step B2. In the sub step B1, the fluxgate sensor 10 is used to measure the magnetic field intensity corresponding to the measurement point at different time points. In the sub step B2, the magnetic field variation of the magnetic field of the measurement point changing with time is determined based on a difference value between the magnetic field intensity measured at different time points and the steady-state magnetic field intensity. Therefore, the magnetic field variation only represents a magnetic field variation at the measurement point caused by PEMFC 30 state variation.

In step C, PEMFC 30 operating state is determined according to a corresponding relationship between the magnetic field variation and PEMFC 30 operating state. The corresponding relationship between the magnetic field variation and PEMFC 30 operating state may be obtained through theoretical analysis or determined through simulations.

For example, through the following theoretical analyses and simulations, it may be learnt that the corresponding relationship includes: in a case that the magnetic field intensity at the air inlet decreases with time, and the magnetic field intensity at the air outlet increases with time, PEMFC operating state is a water flooding fault state; and in a case that the magnetic field intensity at the air inlet increases with time, and the magnetic field intensity at the air outlet decreases with time, PEMFC operating state is a dehydration fault state.

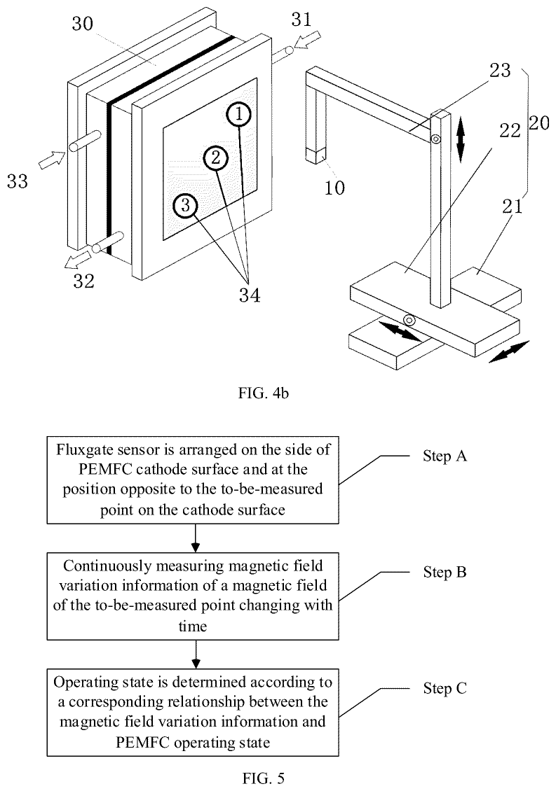

Based on the above-mentioned detection method, in order to determine the corresponding relationship between the magnetic field variation and PEMFC 30 operating state, the present disclosure further provides a simulation method of detecting PEMFC operating state. FIG. 6 is a flowchart of a simulation method of detecting PEMFC operating state according to the present disclosure. As shown in FIG. 4b and FIG. 6, the simulation method includes step D to step G:

In step D, the fluxgate sensor 10 is arranged on PEMFC 30 cathode surface and at the position opposite to the measurement point on the cathode surface.

In step E, simulations are performed on different PEMFC 30 operating states, respectively. In some embodiments of the present disclosure, PEMFC 30 operating states include the water flooding fault state and the dehydration fault state. The water flooding fault state may be simulated by reducing a cathode stoichiometric ratio, and the dehydration fault state may be simulated by reducing a relative humidity of an input gas.

In step F, for the simulation of each operating state, the fluxgate sensor 10 is used to continuously measure the magnetic field variation of the measurement point changing with time.

In some embodiments of the present disclosure, similar to step B, the magnetic field variation is determined based on a difference value between the magnetic field intensity measured at different time points and the steady-state magnetic field intensity.

In step G, the corresponding relationship between PEMFC 30 operating state and the magnetic field variation is determined based on the simulation result. Based on the corresponding relationship, PEMFC 30 operating state may be determined based on variations of the magnetic field at different measurement points.

In the following, water management issues that PEMFC often encounters during operation, such as the water flooding state and the dehydration fault state, are taken as an example to illustrate the technical solution of the present disclosure in detail through simulations. On one hand, a detection effect of the present disclosure when PEMFC being in operation is verified, and on the other hand, an accuracy of the present disclosure is elaborated. It should be noted that the following specific embodiments are only for illustration and are not intended to limit the present disclosure.

The detection apparatus used in the embodiment is as shown in FIG. 4b, where technical parameters of PEMFC 30 and the fluxgate sensor 10 are shown in Table 1 and Table 2.

TABLE 1
Technical parameters of PEMFC system

| Membrane | Membrane | Platinum load | Gas diffusion layer |
|---|---|---|---|
| thickness (μm) | area (cm²) | (mg/cm²) | thickness (μm) |
| 15 | 25 | 0.15@anode, | 260 |
| | | 0.35@cathode | |

TABLE 2
Technical parameters of three-axis fluxgate

| Resolution | Range | Sampling | Temperature |
|---|---|---|---|
| (nT) | (nT) | frequency (Hz) | coefficient (/° C.) |
| 0.1 | 10⁶ | 10 | readings ± 0.03% |

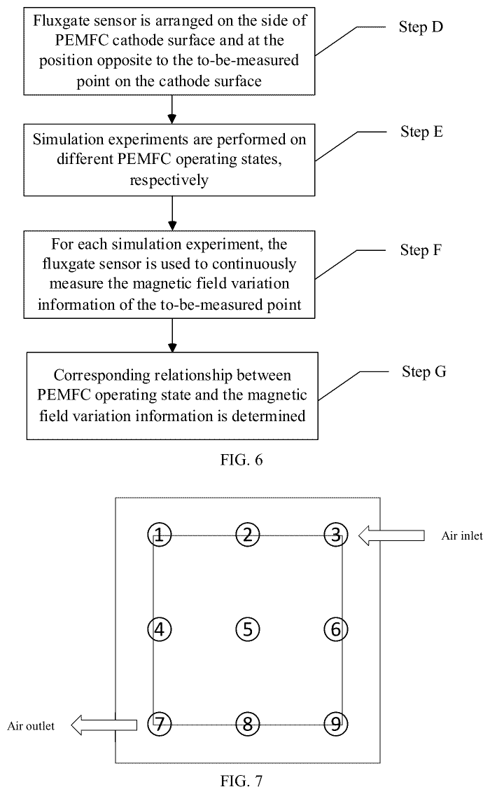

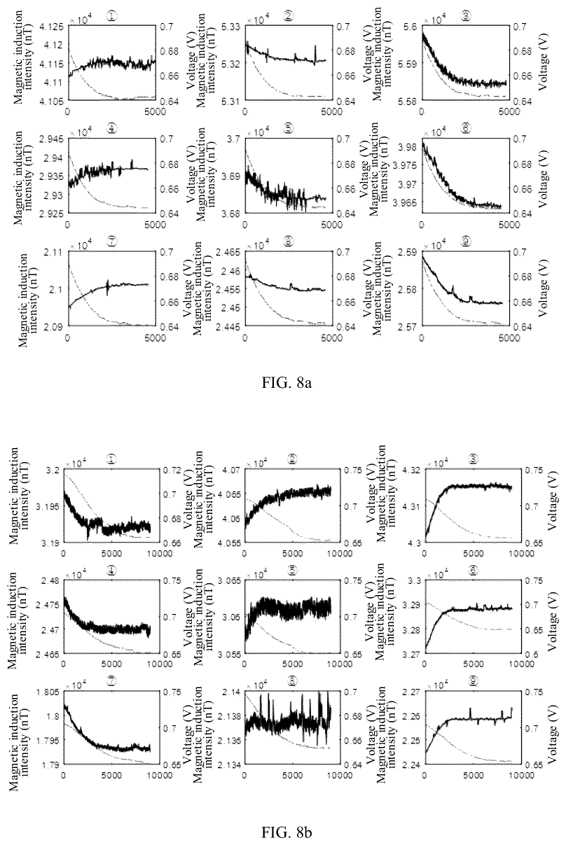

In the simulation, PEMFC 30 water flooding fault and dehydration fault are simulated by reducing the cathode stoichiometric ratio and the relative humidity of the input gas, respectively. The magnetic fields at different measurement points of PEMFC 30 are detected, detection positions are shown in FIG. 7, and specifically, there are nine measurement points. The magnetic field variation, obtained by measuring the magnetic fields of the nine measurement points under the water flooding fault state and the dehydration fault state by using the fluxgate sensor 10, is shown in FIG. 8a and FIG. 8b.

As shown in FIG. 8a and FIG. 8b, the magnetic fields of the same position of PEMFC in different states exhibit a significant difference. Specifically, at the measurement points \textcircled{3}, \textcircled{5}, and \textcircled{7} (which respectively represent the air inlet, the middle position, and the air outlet), during the water flooding fault, the magnetic field intensity at the air inlet decreases with time, and the magnetic field intensity at the air outlet increases with time; during the dehydration fault, the magnetic field intensity at the air inlet increases with time, and the magnetic field intensity at the air outlet decreases with time. It can be seen that the water flooding fault and the dehydration fault may generate opposite magnetic field variations. Therefore, PEMFC operating state and fault may be accurately recognized by detecting variations in the magnetic field.

In addition, as shown in FIG. 8a and FIG. 8b, in an early stage of a PEMFC fault (when a voltage varies slightly), the magnetic field varies significantly instantly. Therefore, PEMFC early fault may be accurately evaluated using the detection method of the present disclosure, so as to provide technical support for formulating of subsequent control and maintenance measures, improving PEMFC reliability and prolonging PEMFC lifespan.

Based on literature researches, the detection results shown in FIG. 8a and FIG. 8b of the embodiment of the present disclosure may be consistent with the existing theory (note: the dotted line represents the voltage, and the solid line represents the magnetic induction intensity). In the case of PEMFC water flooding fault, since an oxygen concentration gradually decreases along with a flow channel, the main current density gradually decreases from the air inlet to the air outlet, water is accumulated at the air outlet, causing the water flooding fault. The membrane current density, as an indicator of a PEMFC abnormal state, reaches its maximum value near the air outlet, which is consistent with the result in FIG. 8a (the magnetic field intensity at the air inlet decreases while the magnetic field intensity near the air outlet increases, indicating the water flooding fault occurs near the outlet). In the case of PEMFC dehydration fault, a degree of dehydration at the air outlet is effectively alleviated due to a generation of liquid water, while at the air inlet, the degree of dehydration reaches its maximum value, which is consistent with the result in FIG. 8b (the magnetic field intensity at the air inlet increases while the magnetic field intensity near the air outlet decreases, indicating the dehydration fault near the outlet).

Based on researches and experimental results, the method and apparatus of detecting PEMFC operating state according to the present disclosure have at least one or part of the following beneficial effects:

1. High diagnostic accuracy: the present disclosure is based on the fluxgate sensor directly detecting the magnetic field variation generated by the membrane current on the surface of MEA in a non-invasive measurement mode. On one hand, PEMFC working state may not be interfered and non-destructive detecting may be achieved, which is different from PEMFC working state being interfered by the embedded sensor in the related art. On the other hand, the detection information is more comprehensive, important fault information may not be omitted, and a robustness of the detection result may be ensured.

2. Beneficial for PEMFC state monitoring: the related art is mainly limited to analyzing two states: before the fault occurs and after the fault occurs. However, a fault formation process and a corresponding mechanism may not be monitored. However, the present disclosure may monitor magnetic fields at different PEMFC positions, and predict the occurrence of different PEMFC faults in a timely manner based on variations in the magnetic field data. Therefore, real-time and accurate PEMFC fault prediction may be achieved, which may provide a basis for formulating subsequent control and maintenance strategies, and is conducive to improving the reliability and a lifespan of PEMFC operation.

3. Beneficial for commercial popularization: the existing magnetic field detection sensor needs to be fixed around PEMFC, the practical commercial application thereof is inconvenient, and a large number of sensors are arranged, resulting in complex wiring and high equipment costs. The present disclosure uses the fluxgate sensor for cathode surface scanning, which may collect multi-point magnetic field data with a single probe, and may avoid data collection, wiring arrangement, and equipment cost issues caused by placing a large number of magnetic field sensors, and the movable detection apparatus may be used more conveniently in practical application scenarios, which is convenient for commercial popularization.

The specific embodiments described above further explain objectives, technical solutions and beneficial effects of the present disclosure in detail. It should be understood that the specific embodiments described above are only specific embodiments of the present disclosure, and should not be used to limit the present disclosure. Any modifications, equivalent substitutions, improvements and the like made within the spirit and principle of the present disclosure should be included in the protection scope of the present disclosure.

What is claimed is:

1. A method of detecting PEMFC (proton exchange membrane fuel cell) operating state, comprising:
arranging a fluxgate sensor on PEMFC cathode surface and at a position opposite to a measurement point on the cathode surface;
when PEMFC is operating, continuously measuring a magnetic field variation of a magnetic field of the measurement point changing with time by using the fluxgate sensor; and
determining PEMFC operating state according to a corresponding relationship between the magnetic field variation and PEMFC operating state.

2. The method according to claim 1, wherein the fluxgate sensor is configured to be movable in three dimensions in a space so as to measure magnetic field variation corresponding to different measurement points on the cathode surface, respectively.

3. The method according to claim 2, wherein the fluxgate sensor is arranged on a bracket, and the bracket comprises:
a base;
a sliding seat arranged on the base, wherein the sliding seat is movable in a first direction and a second direction relative to the base; and
a lifting rod arranged on the sliding seat, wherein the lifting rod is movable in a third direction relative to the sliding seat, and the lifting rod is provided with the fluxgate sensor; and
wherein the first direction, the second direction, and the third direction are perpendicular to each other.

4. The method according to claim 2, wherein the method further comprises:
when PEMFC is not operating, measuring a steady-state magnetic field intensity of the measurement point by using the fluxgate sensor; and
wherein the continuously measuring a magnetic field variation of a magnetic field of the measurement point changing with time by using the fluxgate sensor comprises:
measuring a magnetic field intensity corresponding to the measurement point at different time points by using the fluxgate sensor; and
determining the magnetic field variation of the magnetic field of the measurement point changing with time based on a difference value between the magnetic field intensity measured at different time points and the steady-state magnetic field intensity.

5. The method according to claim 1, wherein PEMFC operating state comprises a water flooding fault state and a dehydration fault state, and the measurement point comprises an air inlet, an air outlet, and a middle position between the air inlet and the air outlet; and
wherein the corresponding relationship between the magnetic field variation and PEMFC operating state comprises:
in a case that a magnetic field intensity at the air inlet decreases with time and a magnetic field intensity at the air outlet increases with time, PEMFC operating state is the water flooding fault state; and
in a case that the magnetic field intensity at the air inlet increases with time and the magnetic field intensity at the air outlet decreases with time, PEMFC operating state is the dehydration fault state.

6. An apparatus of detecting PEMFC (proton exchange membrane fuel cell) operating state, comprising:
a fluxgate sensor arranged on PEMFC cathode surface and at a position opposite to a measurement point on the cathode surface,
wherein when PEMFC is operating, the fluxgate sensor is capable of continuously measuring a magnetic field variation of a magnetic field of the measurement point changing with time, so as to determine PEMFC operating state according to the magnetic field variation.

7. The apparatus according to claim 6, wherein the apparatus further comprises a bracket, and the bracket comprises:
a base;
a sliding seat arranged on the base, wherein the sliding seat is movable in a first direction and a second direction relative to the base; and
a lifting rod arranged on the sliding seat, wherein the lifting rod is movable in a third direction relative to the sliding seat, and the lifting rod is provided with the fluxgate sensor; and
wherein the first direction, the second direction, and the third direction are perpendicular to each other.

8. A simulation method of detecting PEMFC (proton exchange membrane fuel cell) operating state, comprising:
arranging a fluxgate sensor on PEMFC cathode surface and at a position opposite to a measurement point on the cathode surface;
performing simulations on different PEMFC operating states, respectively; and
for the simulation of each operating state, continuously measuring a magnetic field variation of a magnetic field of the measurement point changing with time by using the fluxgate sensor, so as to determine a corresponding relationship between the magnetic field variation and PEMFC operating state.

9. The simulation method according to claim 8, wherein the different operating states comprise a water flooding fault state and a dehydration fault state;
wherein the performing simulations on different PEMFC operating states comprises:
simulating the water flooding fault state by reducing a cathode stoichiometric ratio, and simulating the dehydration fault state by reducing a relative humidity of an input gas.

10. The simulation method according to claim 8, further comprising:
when PEMFC is not operating, measuring a steady-state magnetic field intensity of the measurement point by using the fluxgate sensor;
wherein the continuously measuring a magnetic field variation of a magnetic field of the measurement point changing with time by using the fluxgate sensor comprises:
measuring a magnetic field intensity corresponding to the measurement point at different time points by using the fluxgate sensor; and
determining the magnetic field variation of the magnetic field of the measurement point changing with time based on a difference value between the magnetic field intensity measured at different time points and the steady-state magnetic field intensity.
